(19) United States
(12) Patent Application Publication
(10) Pub. No.: US 2025/0028081 A1
(43) Pub. Date: Jan. 23, 2025

(54) OPTICAL SURFACE OF A HIGH-PRECISION METAL MIRROR WITH VERY LOW ROUGHNESS AND SHAPE DEFECT

(71) Applicant: SAFRAN REOSC, SAINT PIERRE DU PERRAY (FR)

(72) Inventors: Thierry LAGRANGE, MOISSY-CRAMAYEL (FR); Cédric JOSEPH, MOISSY-CRAMAYEL (FR); Guillaume FOUCAUD, MOISSY-CRAMAYEL (FR); Jean-Marc MERCERON, MOISSY-CRAMAYEL (FR); Jacques RODOLFO, MOISSY-CRAMAYEL (FR)

(73) Assignee: SAFRAN REOSC, SAINT PIERRE DU PERRAY (FR)

(21) Appl. No.: 18/715,571

(22) PCT Filed: Dec. 2, 2022
(86) PCT No.: PCT/FR2022/052228

§ 371 Date: May 31, 2024

(30) Foreign Application Priority Data
Dec. 2, 2021 (FR) FR2112744

(51) Int. Cl. G02B 1/10; C23C 14/02; C23C 14/16; C23C 14/58

(52) U.S. Cl. CPC G02B 1/10; C23C 14/022; C23C 14/024; C23C 14/028; C23C 14/165; C23C 14/588

(57) ABSTRACT

The present invention relates to a method of manufacture (S) of an optical surface (4) of an optical part (1), comprising the following steps: obtaining (S1) an optical part (1) comprising a substrate (3) made of a first aluminium alloy and a coating (2) made of a second aluminium alloy having a porosity less than that of the first aluminium alloy; determining (S3) a reference shape defect and a reference surface roughness of the optical surface (4); determining (S4) polishing parameters for obtaining the reference surface roughness; depending on the polishing parameters, machining (S5) the coating (2) so as to give it a modified shape defect; and polishing (S6) the coating (2) according to the polishing parameters until the reference surface roughness and the reference shape defect are obtained.

### TECHNICAL FIELD

The present disclosure generally relates to the field of optical surface polishing of an optical part. The disclosure particularly finds application in the manufacture of high-precision metal mirrors for space, astronomical applications, or for observations.

### BACKGROUND

Metal mirrors have numerous applications in the optical sector.

Said mirrors are generally obtained by applying a metal coating, typically in aluminium, onto a substrate composed of another metal or other material such as glass. However, when these mirrors are subjected to variations in temperature, as is particularly the case in space and military applications, the surface of the mirror undergoes differential deformations (bimetallic effect).

It has therefore been proposed to polish the surface of substrates composed of a single metal or metal alloy. This effectively prevents problems caused by differences in thermal properties. Aluminium is a metal generally given priority for the manufacture of said mirrors on account of the low density, low cost, and compatibility thereof with conventional surface forming processes. The performance of these mirrors in optical applications is highly dependent on the surface which must be very uniform to minimize scattering of light caused by surface irregularities.

The parameters of surface roughness relevant for optical performance not only comprise the mean surface roughness (Ra) or root mean square roughness (Rq), but also important parameters comprising Rmax and/or Rz. Rm3x is the maximum peak to valley height in a given sampling region, where the peak represents a top point on the surface and the valley represents the depth of a scratch on the surface.

Rz is a mean value of Rmax measured in several separate sampling regions. Not only must the mean surface roughness be low for good optical performance, but Rz, Rmax or associated parameters must also be low to minimize light scattering.

It has also been proposed to apply a nickel layer via electroplating onto the substrate of the mirror and then to polish the second metal layer to reduce light scattering. However, the mirrors obtained being composed of different metals, they are mechanically and optically unstable under temperature variations.

It has also been proposed to polish aluminium surfaces to reduce the mechanical and optical instability thereof. Two methods are routinely used.

In the field of optics, polishing is performed by diamond machining to produce mirrors in aluminium useful for reflecting infrared light (e.g. of long wavelength). For diamond polishing, a substrate in aluminium is set in rotation whilst remaining in contact with a diamond cutting tool precisely positioned on the surface of the substrate. The diamond cutting tool «peels off» a very thin layer of aluminium from the surface of the substrate to form a surface having a precisely defined geometry. However, the roughness obtained with said method is limited to 5 nm RMS (root mean square) and does not allow the obtaining of sufficient shape defects on non-planar surfaces, and particularly on freeform surfaces.

An improvement on the diamond machining method is to deposit a polish layer on the mirror and to finish the polishing of this layer. The material regularly used for this layer is NiP (Kanigen) which can be polished to good performance. However, this material has a coefficient of thermal expansion differing from that of the aluminium used for the substrate, which means that the mirror is thermally unstable making this solution difficult to use.

Polishing can also be carried by lapping. For lapping, a suspension of abrasive particles—generally of aluminium oxide or silicon carbide in a solvent comprising water or oil—is used to polish an aluminium surface by moving a pad over the surface of the aluminium to entrain the abrasive suspension and abrade the aluminium surface via mechanical action of the abrasive. However, lapping generates aluminium scourings which tend to produce micro-scratches on the polished surface, leading to an unacceptable surface defect for optical applications.

### SUMMARY

It is one objective of the present disclosure to overcome the aforementioned drawbacks by proposing a method of manufacturing an optical surface of a planar or freeform metal optical part, allowing very low surface roughness to be obtained e.g. less than two nanometres RMS, and very low shape defect e.g. in the region of 15 nm RMS, the method overcoming issues of deformation related to variations in temperature and in particular allowing use at cryogenic temperature.

The method applies in particular to optical parts of large size (typically 400 mm), having a freeform surface and/or non-circular contour.

For this purpose, in a first aspect, there is proposed a method of manufacturing an optical surface of an optical part comprising the following steps:

obtaining an optical part comprising a substrate and a coating, the coating being applied onto one surface of the substrate and being configured to form an optical surface of the optical part, the substrate being made of a first aluminium alloy and the coating being made of a second aluminium alloy having lesser porosity than the porosity of the first aluminium alloy;

determining a reference shape defect and reference surface roughness of the optical surface, and an initial shape defect and initial surface roughness of the coating;

determining polishing parameters, from the initial surface roughness, allowing a reference surface roughness to be obtained;

as a function of the polishing parameters, machining the coating to impart thereto a modified shape defect; and

polishing the machined coating by smoothening, conforming to the determined polishing parameters, to modify the surface roughness and shape defect of the coating until the reference surface roughness and reference shape defect are obtained.

Some preferred but nonlimiting characteristics of the method of manufacture according to the first aspect are the following, taken alone or in combination:
the machining step is performed by ion-beam machining or magnetorheological finishing;
the polishing step is performed using a polishing pad and aqueous diamond polishing agent;
the method further comprises a thermal stabilization step of the optical part;
the thermal stabilization step is performed before the determination step of the initial shape defect and initial surface roughness and/or after the polishing step;
the method further comprises a cleaning step with the contactless application of water vapour to the optical surface;
the method further comprises a vacuum drying step of the optical part after the cleaning step;
the step to obtain the optical part comprises a prior machining step of the substrate to obtain an initial shape defect smaller than an initial thickness of the coating and an initial roughness of no more than 15 nm RMS, e.g. 10 nm RMS;
the method further comprises: a step to determine the modified surface roughness and modified shape defect after the polishing step; and if the modified surface roughness and/or modified shape defect differ from the reference surface roughness and/or reference shape defect: determining new polishing parameters to obtain the reference surface roughness; as a function of the new polishing parameters, machining the coating to impart thereto a modified shape defect; and polishing the machined coating by smoothening, conforming to the new determined polishing parameters, to modify the surface roughness and modified shape defect of the coating, until the reference surface roughness and reference shape defect are obtained.

In a second aspect, there is proposed an optical part comprising a substrate and an optical surface applied onto one surface of the substrate, the substrate being made of a first aluminium alloy and the optical surface being made of a second aluminium alloy having lesser porosity than the porosity of the first aluminium alloy and being obtained conforming to the method of manufacture according to the first aspect.

Optionally, a surface roughness of the optical surface is less than or equal to 2 nm RMS and a shape defect of the optical surface is less than or equal to 15 nm RMS.

### DESCRIPTION OF THE FIGURES

Other characteristics, objectives and advantages of the invention will become apparent from the following description which is solely illustrative and nonlimiting and is to be read in connection with the appended drawings in which:

FIG. 1 is a flowchart of the steps of an example of the method of manufacture according to one embodiment of the invention;

FIG. 2a very schematically illustrates an optical part obtained after step S1 of the method of manufacture; and

FIG. 2b illustrates the optical part in FIG. 2a after implementing the steps of the method of manufacture.

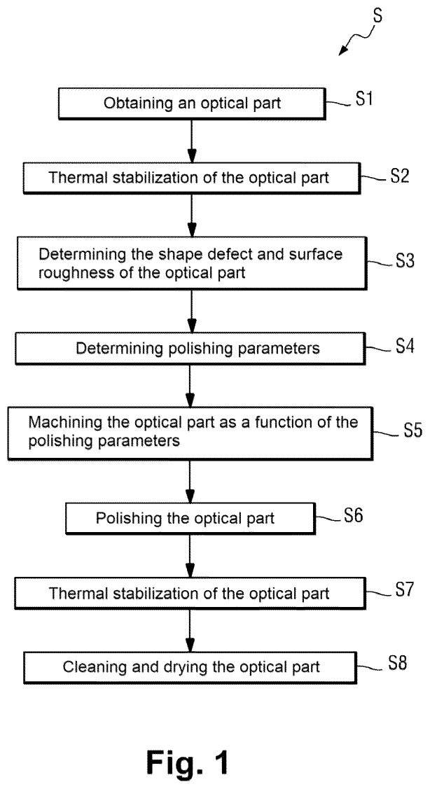

In all the Figures, similar elements carry same references.

### DETAILED DESCRIPTION

A method of manufacture S is proposed herein of the optical surface 4 of an optical part 1 allowing very low surface roughness and shape defect to be obtained, even when the optical part 1 is of large size (typically 400 mm), having a freeform surface (i.e. the surface having a radial profile and arbitrary angle variations) and/or a non-circular contour.

For this purpose, a method of manufacture S is proposed comprising the following steps:

S1: obtaining an optical part 1 comprising a coating 2 on a substrate 3, the coating 2 being configured to form an optical surface 4 of the optical part 1;

S3: determining a reference shape defect and reference surface roughness of the optical surface 4, and an initial shape defect and initial surface roughness of the coating 2;

S4: determining polishing parameters, from the initial surface roughness, allowing the reference surface roughness to be obtained;

S5: as a function of the polishing parameters, machining (S5) the coating 2 to impart thereto a modified shape defect; and

S6: polishing the machined coating 2 by smoothening, conforming to the determined polishing parameters, to modify the surface roughness and shape defect of the coating 2, until the reference surface roughness and reference shape defect are obtained.

It is therefore proposed to combine a machining step S5 of the coating 2, to reduce the shape defect thereof, with a polishing step S6 by smoothening, to reduce the roughness thereof and obtain the optical surface 4. In addition, the machining step S5 is performed in a manner to take into account the (inevitable) deformations resulting from the subsequent polishing step S6 the objective of which is to obtain the desired reference surface roughness. The polishing step S6 necessarily induces shape defects on the coating 2 via smoothening effect. Yet, as will be seen below, said smoothening effect (and hence the corresponding shape defect) can be anticipated and therefore taken into consideration at the prior machining step S5. Therefore, the shape defect obtained after the machining step S5 does not correspond to the reference shape defect which is sought for the optical surface 4, but to an intermediate shape defect, the shape of the coating 2 later being modified by the polishing step S6. On the other hand, after the polishing step S6, the shape defect of the coating 2 corresponds to the desired reference shape defect for the optical surface 4.

The reference shape defect for example can be less than or equal to fifteen nanometres, and the reference surface roughness for example can be less than or equal to two nanometres for a freeform optical surface 4 having a size in the region of 400 mm.

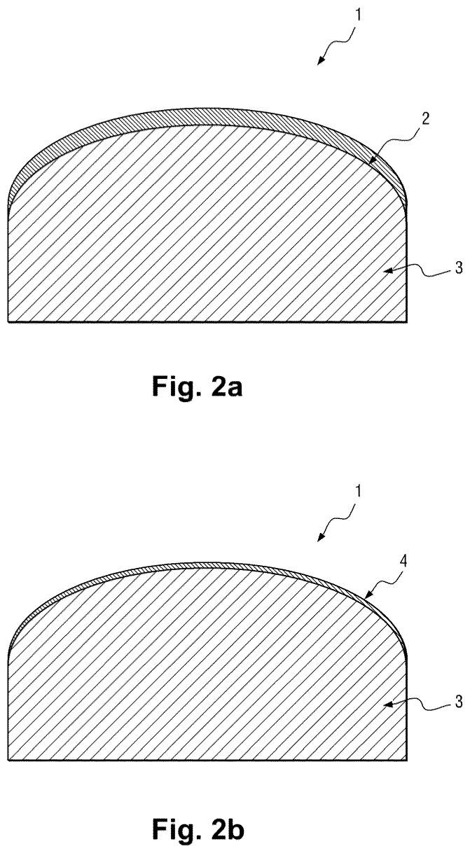

At step S1, the optical part 1 is obtained (FIG. 2a).

The substrate 3 is made of a first aluminium alloy having good mechanical performance and preferably a coefficient of thermal expansion similar to that of the coating 2 (typically a difference in coefficient of thermal expansion less than (5×10\hat{ }−6 K\hat{ }−1), for example one of the following alloys: aluminium alloy 6061 (e.g. 6061-T6), 2017A, 2021 or the 70xx family of alloys.

The coating 2 is applied onto one surface of the substrate 3 and is monolithic with the substrate 3. The coating 2 is made of a second aluminium alloy differing from the first aluminium alloy. The second alloy is dense in that it has lesser porosity than the porosity of the first alloy. For example, the second alloy may comprise at least 99% pure aluminium (deposited by vacuum evaporation). Optionally, the coating 2 may evidently be applied to all the surfaces of the substrate.

The coating 2 can be deposited by spraying or evaporation on the surface of the substrate 3. A thickness of the coating 2 is for example between ten micrometres and twenty micrometres. The shape defect of the optical part 1 is less than the thickness of the coating 2, e.g. in the region of 150 nm, typically in the region of 100 nm for an aspherical substrate of mean size 300 mm.

When the shape defect of the substrate 3 is greater than the thickness of the coating to be deposited, step S1 comprises machining of the substrate 3 to reduce the shape defect thereof. This prior machining SO can be carried for example by diamond machining. Reference can be made for example to the article «Diamonds turn infrared mirrors smooth» by Daniel Vukobratovich et al., Optoelectronics World, pp. S25-S28, Octobrer1998 for more details on this type of machining.

Optionally, the method S further comprises a thermal stabilization step S2 at which heat treatment is applied to the optical part 1 for thermal stabilization thereof and to prevent the shape of the part from changing over time as a function of temperature variations.

For example, heat treatment comprising several heat treat treatment cycles is carried out each for at least two hours, for example each for three to five hours, at which the temperature applied to the optical part 1 ranges from a first temperature of no more than −50° C. for example of −80° C., to a second temperature of at least +120° C., for example +150° C. for each cycle, preferably under a dry atmosphere to prevent degradation of roughness. At each cycle, the temperature is held at the first temperature for a predetermined time, for example between about thirty minutes and two hours, and is then gradually increased until the second temperature is reached, for example at a temperature ramp of +2°/min; the temperature is stabilized at the second temperature for a predetermined time, for example between about thirty minutes and two hours, before being gradually lowered to the first temperature, typically at a temperature ramp of −2°/min. A total of six cycles (2 h at '50° C., 1 h transition phase, 2 h at +120° C., 1 h transition phase) can be carried out i.e. heat treatment lasting 39 h.

Another example of stabilizing heat treatment able to be applied herein is described in document «The primary mirror of the ARIEL mission: study of thermal, figuring, and finishing treatments and optical characterization of AI 6061 samples mirrors», Chioetto et al., Proc. SPIE 11116, Astronomical Optics: Design, Manufacture, and Test of Space and Ground Systems II, 111161C.

It is possible to omit this step S2 if the optical part 1 obtained at step S1 is already thermally stable.

At step S3, the initial shape defect and initial surface roughness of the coating 2 are determined. This step can be performed for example using an interferometer to measure shape defect and an optical roughometer to measure roughness.

At step S4, the polishing parameters, allowing the reference surface roughness to be obtained, are determined from the initial surface roughness.

The polishing parameters may comprise at least one of the following parameters: the rotation and progression speed of the polishing pad, the number of polishing cycles needed to progress from the initial surface roughness to the reference surface roughness, the travel path (generally random) of the polishing pad on the coating 2, the physical characteristics of the polishing pad, the physical characteristics of the polishing abrasive, the pressure applied by the polishing pad on the coating 2, the second metal alloy.

The degradation of the shape defect by polishing being known for each polishing cycle as a function of the polishing parameters, a numerically controlled machine is able to compute a wear function from the polishing parameters allowing determination of the number of polishing cycles required to reduce the surface roughness of the coating 2 and reach the reference surface roughness, and can infer therefrom the deformation (smoothening effect) which will be undergone by the optical part 1 at the polishing step.

Optionally, the method S may comprise a prior polish calibration step to determine the polishing parameters. For this purpose, a smoothening tool can be applied to an identical optical part 1 i.e. having substantially the same substrate 3 and coating 2 as those of the optical part 1 to be manufactured, to calibrate the deformation induced by the smoothening tool on the coating 2.

At step S5, a numerically controlled machine determines the machining parameters of the coating 2 and sends machining instructions for the coating 2 to a machining tool to obtain a modified shape defect of the coating 2. The modified shape defect corresponds to an intermediate shape defect, obtained after the machining step and before the polishing step S6. This intermediate shape defect takes into account the deformation of the coating 2 inherent in the subsequent polishing step S6 so that, once the machining and polishing steps have been completed, the shape defect obtained corresponds to the reference shape defect. In other words, the reference shape defect corresponds to the sum of the modified shape defect (intermediate) and the deformation resulting from the polishing step (smoothening effect). The consideration given to the deformation resulting from the subsequent polishing step S6, is necessary when it is sought to obtain a very small shape defect, typically less than or equal to 15 nm RMS. In one embodiment, step S5 is performed by ion-beam machining with an ion-beam gun in a vacuum environment. The ion-beam gun may comprise a multi-axe robot (typically 6 axes) on which an ion source is mounted generating an ion beam of energy between 800 eV and 1500 eV and having a mid-height width of between 5 mm and 25 mm.

As a variant, step S5 can be performed on a magnetorheological finishing machine (MRF) where a magnetic flow is applied to a polishing fluid loaded with magnetic particles and this fluid applied to the coating 2. The polishing fluid then forms a polishing tool allowing machining of the coating 2 under shear, and correction of the shape defect.

At step S6, the coating 2 is polished by smoothening. This polishing step has the effect of modifying the surface roughness and shape defect of the coating 2 and is performed conforming to the polishing parameters determined at step S4 until the reference surface roughness and reference shape defect are obtained (FIG. 2b).

The polishing step can be carried out for example with a smoothening tool having a diameter between 10 mm and 50 mm, for example about 20 mm, following the contour of the surface of the substrate 3 of the optical part 1. The smoothening tool must be sufficiently rigid to reduce the roughness of the coating 2 and sufficiently deformable to follow the contour of the surface of the substrate carrying the coating 2, to limit (even eliminate) risks of degrading the substrate 3. The smoothening tool for example may comprise a thin brass disc (typically of one millimetre thickness). A polishing pad is mounted on the smoothening tool and a polishing agent (abrasive), typically diamond-based, comprising a solvent in which the abrasive particles are suspended, is applied to the coating 2. The polishing pad is configured so that the polishing agent particles cling thereto and are homogeneously entrained by the rotation and movement of the polishing tool on the coating 2, without scratching the coating 2. It is therefore the polishing agent which reduces the surface roughness of the coating 2. The polishing pad may comprise a fibrous or felt fabric for example. The polishing agent can be water-based.

The smoothening tool can be applied to the coating 2 with a pressure of approximately 2 kg for example for a tool of diameter 20 mm. The rotation speed of the polishing tool can be approximately 500 rpm. The travel path of the smoothening tool is chosen so as not to generate singularities on the part and can typically be random as described in the article «Pseudo-random tool paths for CNC sub-aperture polishing and other applications» by Christina R. Dunn et al., OSA Vol. 16, No. 23/OPTICS EXPRESS 18942.

Once the polishing step S6 is completed conforming to the polishing parameters identified at step S4, the optical part 1 has an optical surface 4 having a shape defect and surface roughness corresponding to the reference shape defect and reference surface roughness.

If the surface roughness and/or shape defect obtained after the polishing step S6 do not correspond to the reference surface roughness and/or reference shape defect, steps S3 to S6 are repeated. In particular, new polishing and machining parameters are determined from the surface roughness and shape defect obtained after step S6, to obtain the reference surface roughness and reference shape defect, after which the coating is machined S5 and polished S6 conforming to the new polishing parameters until the reference surface roughness and reference shape defect are obtained.

The machining S5 and polishing S6 steps may cause relaxing of stresses in the substrate 3 or in the coating 2 of the optical part 1, leading to deformation of the part. To avoid this deformation, the method S may further comprise a thermal stabilization step S7 at which heat treatment is applied to the optical part 1 obtained after the polishing step S6. This heat treatment can obviate deformations related to relaxing of stresses in the optical part 1, obtaining thermal stabilization so that the shape of the optical part 1 does not alter over time and/or as a function of temperature.

For example, heat treatment comprising several heat treatment cycles is carried out for at least two hours, for example for two to four hours. In particular, the same thermal stabilization treatment as described at step S2 can be applied at step S7. The optical part 1 is then stable and in particular is not affected by deformation problems related to temperature variations. In particular, it can be used at cryogenic temperature.

On the other hand, this step is optional if the envisaged applications for the optical part 1 are at ambient temperature.

At step S8, the optical part 1 is cleaned and dried. Preferably, cleaning and drying are contactless operations to avoid scratching the optical surface 4.

Cleaning and drying can be conventional operations. As a variant, so as not to damage the optical surface and in particular not degrade the shape defect or surface roughness obtained at step S6, the cleaning step can be performed by contactless application of water vapour to the optical surface 4. The water vapour may comprise a mixture of mains water and deionized water in a proportion of 10:90.

Drying can be obtained by placing the optical part 1 in a vacuum (10\hat{ }−2 bar) for 5 h with a compressed inert gas e.g. a compressed gas containing nitrogen.

1. A manufacturing method comprising the following steps:
determining a reference shape defect and a reference surface roughness of an optical surface of an optical part, wherein the optical part comprises a substrate and a coating, the coating being applied onto a surface of the substrate and being configured to form the optical surface of the optical part, the substrate being made of a first aluminium alloy and the coating being made of a second aluminium alloy having lesser porosity than a porosity of the first aluminium alloy;
determining an initial shape defect and initial surface roughness of the coating of the optical part;
using the initial surface roughness, to determine polishing parameters required to obtain the determined reference surface roughness;
using the polishing parameters to machine the coating and obtain a machined coating having a machined shape defect; and
using the determined polishing parameters to polish the machined coating by smoothening in order to modify the surface roughness and machined shape defect of the machined coating and obtain modified surface roughness and modified shape defect that correspond to the determined reference roughness and reference shape defect.

2. The manufacturing method according to claim 1, wherein machining is performed by ion-beam machining or by magnetorheological finishing.

3. The manufacturing method according to claim 1, wherein polishing is performed with a polishing pad and an aqueous diamond polishing agent.

4. The manufacturing method according to claim 1, further comprising thermal stabilization of the optical part.

5. The manufacturing method according to claim 1, wherein thermal stabilization is performed before determine the initial shape defect and the_initial surface roughness and/or after polishing of the machined coating.

6. The manufacturing method according to claim 1, further comprising contactless cleaning of the optical surface with water vapour.

7. The manufacturing method according to claim 6, further comprising vacuum drying of the optical part after cleaning of the optical surface.

8. The manufacturing method according to claim 1, wherein, prior to determining the initial shape defect and the initial surface roughness, the manufacturing method comprises machining step the substrate so that the initial shape defect is smaller than an initial thickness of the coating and the initial roughness is less than 15 nm RMS.

9. The manufacturing method according to claim 1, further comprising:
determining the modified surface roughness and modified shape defect; and
if at least one of the modified surface roughness and the modified shape defect differ from the reference surface roughness or the reference shape defect, respectively:
determining new polishing parameters to obtain the reference surface roughness;
depending on the new polishing parameters, machining the machined coating to obtain a further modified shape defect; and
using the new polishing parameters to polish the machined coating by smoothening in order to further modify the modified surface roughness and the modified shape defect of the coating (2) and obtain the reference surface roughness and reference shape defect.

10. An optical part comprising a substrate and an optical surface applied to a surface of the substrate, the substrate being made of a first aluminium alloy and the optical surface being made of a second aluminium alloy having lesser porosity than the porosity of the first aluminium alloy and being obtained according to the manufacturing method according to claim 1.

11. The optical part according to claim 10, wherein a surface roughness of the optical surface is less than or equal to 2 nm RMS, and a shape defect of the optical surface is less than or equal to 15 nm RMS.

12. The manufacturing method according to claim 8, wherein the substrate is machined so that the initial roughness is 10 nm RMS.
